(19) United States
(12) Patent Application Publication
(10) Pub. No.: US 2024/0194706 A1
(43) Pub. Date: Jun. 13, 2024

(54) SOLID-STATE IMAGING DEVICE

(71) Applicant: SONY SEMICONDUCTOR SOLUTIONS CORPORATION, KANAGAWA (JP)

(72) Inventor: YASUHIRO EBIHARA, KANAGAWA (JP)

(21) Appl. No.: 18/555,553

(22) PCT Filed: Jan. 12, 2022
(86) PCT No.: PCT/JP2022/000800

§ 371 Date: Oct. 16, 2023

(30) Foreign Application Priority Data
May 6, 2021 (JP) 2021-078800

(51) Int. Cl. H01L 27/146

(52) U.S. Cl. CPC H01L 27/14616

(57) ABSTRACT

A solid-state imaging device includes a first semiconductor layer, a transistor, and an electric field relaxation section. The transistor includes: a fin provided to stand on a main surface section of the first semiconductor layer; a first main electrode, a channel-forming region, and a second main electrode that are provided in the fin along a channel length direction; and a gate insulating film and a gate electrode that cover an upper surface and a side surface of the fin to extend over the fin along a channel width direction. The electric field relaxation section is provided in a lower part of the side surface of the fin to relax electric field concentration.

### TECHNICAL FIELD

The present disclosure relates to a solid-state imaging device.

### BACKGROUND ART

For example, PTL 1 discloses a semiconductor device with an imaging element stacked therein. In the imaging element, a transistor that constitutes part of a logic circuit is coupled to a photodiode. The transistor is an amplification transistor adopting a fin structure (a Fin-FET).

In the transistor, a fin is formed; the fin has a source region, a channel-forming region, and a drain region, and is provided to stand on a substrate. A gate insulating film and a gate electrode are formed along the fin in a channel width direction.

According to the transistor adopting such a structure, it is possible to gain a channel width dimension along the fin, and therefore it is possible to make the effective area of a current path larger. Thus, it is possible to improve noise characteristics.

### CITATION LIST

### Patent Literature

PTL 1: Japanese Unexamined Patent Application Publication No. 2018-129374

### SUMMARY OF THE INVENTION

Improvement in dielectric strength of a gate insulating film is expected of a transistor adopting the above-described fin structure.

The present disclosure provides a solid-state imaging device that makes it possible to improve the dielectric strength of a transistor adopting the fin structure.

A solid-state imaging device according to an embodiment of the present disclosure includes: a first semiconductor layer; a transistor including a fin provided to stand on a main surface section of the first semiconductor layer, a first main electrode, a channel-forming region, and a second main electrode that are provided in the fin along a channel length direction, and a gate insulating film and a gate electrode that cover an upper surface and a side surface of the fin to extend over the fin along a channel width direction; and an electric field relaxation section provided in the lower part of the side surface of the fin to relax electric field concentration.

### BRIEF DESCRIPTION OF DRAWINGS

FIG. 1A is a cross-sectional view of a main part, including pixels and a pixel circuit, of a solid-state imaging device according to a first embodiment of the present disclosure.

FIG. 1B is a plan view of the main part including the pixel circuit illustrated in FIG. 1A.

FIG. 2 is a circuit diagram of the pixels and the pixel circuit illustrated in FIG. 1A.

FIG. 3 is a cross-sectional view of a main part corresponding to FIG. 1A, which illustrates a pixel circuit of a solid-state imaging device according to a second embodiment of the present disclosure.

FIG. 4 is a cross-sectional view of a main part corresponding to FIG. 1A, which illustrates a pixel circuit of a solid-state imaging device according to a third embodiment of the present disclosure.

FIG. 5 is a cross-sectional view of a main part corresponding to FIG. 1A, which illustrates a pixel circuit of a solid-state imaging device according to a fourth embodiment of the present disclosure.

FIG. 6 is a cross-sectional view of a main part corresponding to FIG. 1A, which illustrates a pixel circuit of a solid-state imaging device according to a fifth embodiment of the present disclosure.

FIG. 7 is a cross-sectional view of a main part corresponding to FIG. 1A, which illustrates a pixel circuit of a solid-state imaging device according to a sixth embodiment of the present disclosure.

FIG. 8 is a cross-sectional view of a main part corresponding to FIG. 1A, which illustrates a pixel circuit of a solid-state imaging device according to a seventh embodiment of the present disclosure.

FIG. 9 is a cross-sectional view of a main part corresponding to FIG. 1A, which illustrates a pixel circuit of a solid-state imaging device according to an eighth embodiment of the present disclosure.

FIG. 10 is a cross-sectional view of a main part corresponding to FIG. 1A, which illustrates a pixel circuit of a solid-state imaging device according to a ninth embodiment of the present disclosure.

FIG. 11 is a cross-sectional view of a main part corresponding to FIG. 1A, which illustrates a pixel circuit of a solid-state imaging device according to a tenth embodiment of the present disclosure.

FIG. 12 is a cross-sectional view of a main part corresponding to FIG. 1B, which illustrates a pixel circuit of a solid-state imaging device according to an eleventh embodiment of the present disclosure.

FIG. 13 is a block diagram depicting an example of schematic configuration of a vehicle control system that is a first application example according to an embodiment of the present disclosure.

FIG. 14 is a diagram of assistance in explaining an example of installation positions of an outside-vehicle information detecting section and an imaging section.

FIG. 15 is a view depicting an example of a schematic configuration of an endoscopic surgery system that is a second application example according to an embodiment of the present disclosure.

FIG. 16 is a block diagram depicting an example of a functional configuration of a camera head and a camera control unit (CCU).

### MODES FOR CARRYING OUT THE INVENTION

With reference to the drawings, embodiments of the present disclosure will be described in detail below. It is noted that the description is made in the following order.

### 1. First Embodiment

A first embodiment describes a first example of the present technology applied to a solid-state imaging device.

### 2. Second Embodiment

A second embodiment describes a second example where in the solid-state imaging device according to the first embodiment, a configuration of an electric field relaxation section is modified.

### 3. Third Embodiment

A third embodiment describes a third example where in the solid-state imaging device according to the first embodiment, the configuration of the electric field relaxation section is modified.

### 4. Fourth Embodiment

A fourth embodiment describes a fourth example where in the solid-state imaging device according to the first embodiment, the configuration of the electric field relaxation section is modified.

### 5. Fifth Embodiment

A fifth embodiment describes a fifth example where in the solid-state imaging device according to the first embodiment, the configuration of the electric field relaxation section is modified.

### 6. Sixth Embodiment

A sixth embodiment describes a sixth example where in the solid-state imaging device according to the first embodiment, the configuration of the electric field relaxation section is modified.

### 7. Seventh Embodiment

A seventh embodiment describes a seventh example where in the solid-state imaging device according to the first embodiment, the configuration of the electric field relaxation section is modified.

### 8. Eighth Embodiment

An eighth embodiment describes an eighth example where in the solid-state imaging device according to the first embodiment, the configuration of the electric field relaxation section is modified.

### 9. Ninth Embodiment

A ninth embodiment describes a ninth example where in the solid-state imaging device according to the first embodiment, the configuration of the electric field relaxation section is modified.

### 10. Tenth Embodiment

A tenth embodiment describes a tenth example where in the solid-state imaging device according to the first embodiment, the configuration of the electric field relaxation section is modified.

### 11. Eleventh Embodiment

An eleventh embodiment describes an eleventh example where in the solid-state imaging device according to the first embodiment, the configuration of the electric field relaxation section is modified.

### 12. Example of Application to Moving Body

There is described an example of the present technology applied to a vehicle control system that is an example of a moving body control system.

### 13. Example of Application to Endoscopic Surgery System

There is described an example of the present technology applied to an endoscopic surgery system.

### 14. Other Embodiments

### 1. First Embodiment

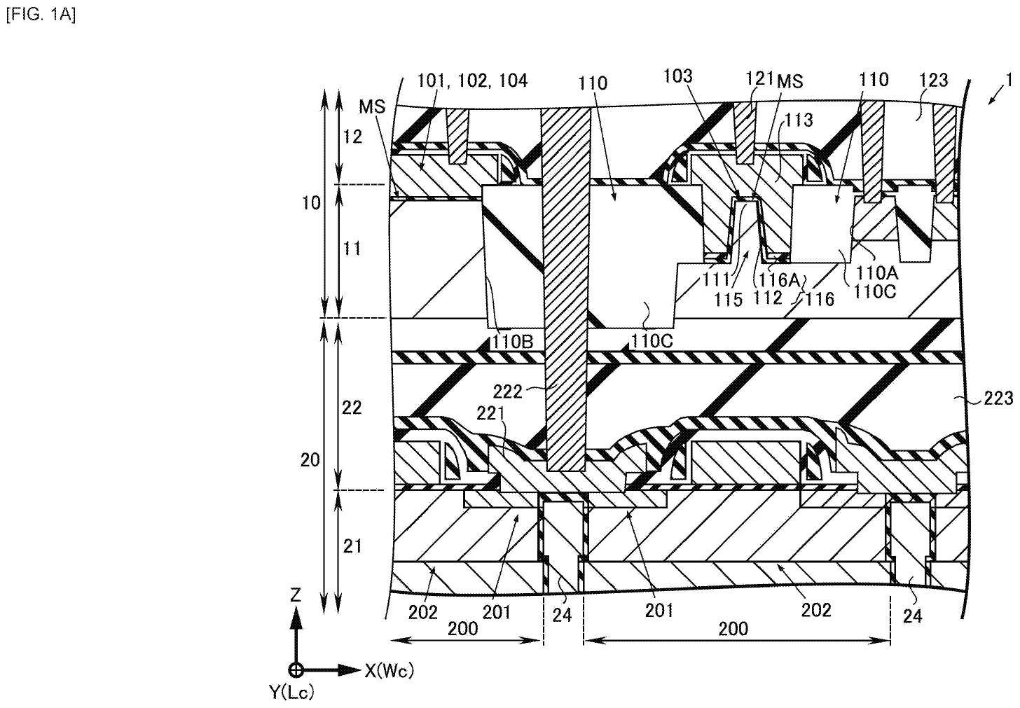

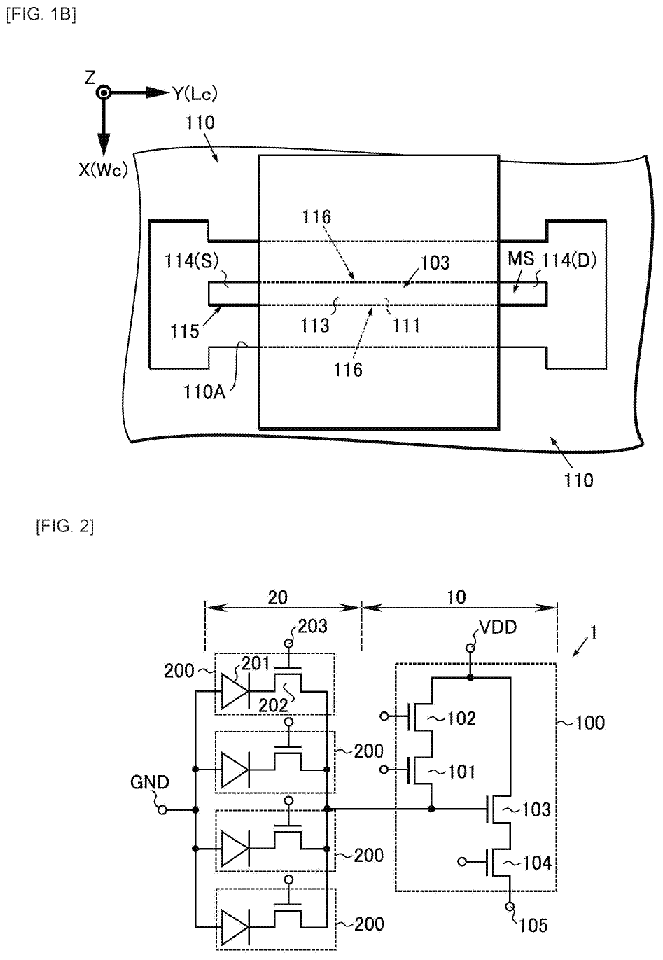

A solid-state imaging device 1 according to the first embodiment of the present disclosure is described with FIGS. 1A, 1B, and 2. FIG. 1A is a cross-sectional view of a main part of the solid-state imaging device 1. FIG. 1B is a plan view of a main part of the solid-state imaging device 1. FIG. 2 is a circuit diagram illustrating a circuit configuration of the solid-state imaging device 1.

Here, an arrow X direction illustrated fittingly in the drawings indicates a direction of one plane surface of the solid-state imaging device 1 placed conveniently on a plane. An arrow Y direction indicates a direction of another plane surface perpendicular to the arrow X direction. Furthermore, an arrow Z direction indicates an upward direction perpendicular to the arrow X direction and the arrow Y direction. That is, the arrow X direction, the arrow Y direction, and the arrow Z direction just correspond to an X-axis direction, a Y-axis direction, and a Z-axis direction of a three-dimensional coordinate system, respectively.

It is noted that these respective directions are illustrated to help understanding of the description, and are not to limit the direction of the present technology.

### [Configuration of Solid-State Imaging Device 1]

### (1) Circuit Configuration of Pixels 200 and Pixel Circuit 100 of Solid-State Imaging Device 1

The solid-state imaging device 1 includes pixels 200 and a pixel circuit 100. FIG. 2 illustrates an example of a circuit configuration of the pixels 200 and the pixel circuit 100 that constitute the solid-state imaging device 1.

One pixel 200 includes a series circuit of a photoelectric conversion element (a photodiode) 201 and a transfer transistor 202.

An anode terminal of the photoelectric conversion element 201 is coupled to a power supply potential (a reference potential) GND. A cathode terminal of the photoelectric conversion element 201 is coupled to one of terminals of the transfer transistor 202. The photoelectric conversion element 201 converts light that has entered from the outside of the solid-state imaging device 1 into an electrical signal.

The other terminal of the transfer transistor 202 is coupled to the pixel circuit 100. A control terminal of the transfer transistor 202 is coupled to a horizontal signal line 203.

The pixel circuit 100 includes a floating diffusion (FD) conversion gain switching transistor 101, a reset transistor 102, an amplification transistor 103, and a selection transistor 104.

The other terminal of the transfer transistor 202 is coupled to one of terminals of the FD conversion gain switching transistor 101 and a control terminal of the amplification transistor 103. The other terminal of the FD conversion gain switching transistor 101 is coupled to one of terminals of the reset transistor 102. The other terminal of the reset transistor 102 is coupled to a power supply potential VDD. One of terminals of the amplification transistor 103 is coupled to one of terminals of the selection transistor 104. The other terminal of the amplification transistor 103 is coupled to the power supply potential VDD. The other terminal of the selection transistor 104 is coupled to a vertical signal line 105.

In the solid-state imaging device 1 according to the first embodiment, one pixel circuit 100 is provided for four pixels 200.

Although detailed description of its circuit configuration is omitted, the solid-state imaging device 1 further includes a peripheral circuit that controls the operation of the pixel circuit 100. The peripheral circuit includes, for example, an input unit, a timing control unit, a row driving unit, a column signal processing unit, an image signal processing unit, and an output unit.

### (2) Vertical Cross-Sectional Configuration of Solid-State Imaging Device 1

FIG. 1A illustrates an example of a vertical cross-sectional configuration of part of the pixels 200 and the pixel circuit 100 of the solid-state imaging device 1.

The solid-state imaging device 1 here is configured as a back-illuminated image sensor. As viewed in the arrow Y direction (hereinafter, referred to simply as “in a side view”), the solid-state imaging device 1 includes a first substrate 10, a second substrate 20, and a non-illustrated third substrate. Here, the first substrate 10 is stacked on top of the second substrate 20. The non-illustrated third substrate is stacked on top of the first substrate 10. That is, the solid-state imaging device 1 includes the second substrate 20, the first substrate 10, and the third substrate stacked on top of another in this order.

### (3) Configuration of Second Substrate 20

The second substrate 20 includes a second semiconductor layer 21 and a second wiring layer 22 provided on the first substrate 10 side of the second semiconductor layer 21. The second semiconductor layer 21 is formed of monocrystalline silicon (Si).

The second semiconductor layer 21 includes the pixels 200. Although its detailed structure is omitted, the photoelectric conversion element 201 of the pixel 200 has an n-type semiconductor region as a cathode region and a p-type semiconductor region as an anode region, and is formed by a p-n junction of the two.

Although not illustrated, on the light incident side of the photoelectric conversion element 201, a light receiving lens is provided through the intervention of a charge fixing film and an insulating film. Here, one light receiving lens is provided for a total of four pixels 200 adjacent in the arrow X direction and the arrow Y direction. It is noted that one light receiving lens may be provided for one pixel 200. The light receiving lens collects light that enters the photoelectric conversion element 201.

The light incident side here is the side opposite to the first substrate 10 side of the second semiconductor layer 21.

Although its detailed structure is also omitted, the transfer transistor 202 of the pixel 200 is included in a surface section of the first substrate 10 side of the second semiconductor layer 21. The transfer transistor 202 includes an n-channel insulated-gate field-effect transistor (IGFET). The transfer transistor 202 includes a pair of main electrodes (terminals) that are a source region and a drain region, a channel-forming region, a gate insulating film, and a gate electrode (a control terminal).

The IGFET here includes at least a metal-oxide-semiconductor field-effect transistor (MOSFET) and a metal-insulator-semiconductor field-effect transistor (MISFET).

Furthermore, a pixel separation region 24 is provided between pixels 200 adjacent in the arrow X direction and the arrow Y direction. The pixel separation region 24 optically and electrically separates the adjacent pixels 200.

The second wiring layer 22 includes an electrode 221, a through wiring line 222, and an insulating layer 223. One end of the electrode 221 is coupled to the transfer transistor 202, and another end of the electrode 221 is coupled to one end of the through wiring line 222. Another end of the through wiring line 222 extends through the insulating layer 223 and a portion of the first substrate 10 in a thickness direction (the arrow Z direction), and, although a coupling structure is not illustrated, here, is coupled to a first wiring layer 12 of the first substrate 10.

The electrode 221 is formed of, for example, polycrystalline silicon (Si) doped with phosphorus (P) as an impurity that decreases a resistance value. The through wiring line 222 is formed of, for example, tungsten (W).

The insulating layer 223 is provided and embedded with the electrode 221 and the through wiring line 222. The insulating layer 223 is actually formed of multiple layers of insulating films stacked on top of another. The insulating layer 223 is formed of silicon oxide films (SiO), silicon nitride films (SiN), or a combination of both.

### (4) Configuration of First Semiconductor Layer 11 of First Substrate 10

The first substrate 10 includes a first semiconductor layer 11 provided on the second substrate 20 side and the first wiring layer 12 provided on the side opposite to the first substrate 10 side of the first semiconductor layer 11. The first semiconductor layer 11 is formed of monocrystalline silicon.

The first semiconductor layer 11 includes the pixel circuit 100. That is, the FD conversion gain switching transistor 101, the reset transistor 102, the selection transistor 104, and the amplification transistor 103 are provided in the first semiconductor layer 11 (see FIG. 2).

Here, the FD conversion gain switching transistor 101, the reset transistor 102, and the selection transistor 104 are the same in basic components. Thus, for simplicity, only a cross-sectional structure of one transistor (for example, the FD conversion gain switching transistor 101) is illustrated in the left side of FIG. 1A. In the right side of FIG. 1A, a cross-sectional structure of the amplification transistor 103 is illustrated.

The FD conversion gain switching transistor 101, the reset transistor 102, and the selection transistor 104 are provided in a main surface section of the first semiconductor layer 11 on the side opposite to the second substrate 20 side. The main surface section here is used in the meaning of a main surface site that forms an element such as a transistor or a resistor.

The FD conversion gain switching transistor 101 is surrounded by an element separation region 110. The element separation region 110 includes a groove 110A dug down from a main surface MS of the first semiconductor layer 11 along the thickness direction and an embedded body 110C embedded in the groove 110A. Furthermore, the element separation region 110 includes a through-hole 110B going through the element separation region 110 along the thickness direction of the first semiconductor layer 11 and an embedded body 110C embedded in the through-hole 110B. The embedded bodies 110C here are formed of silicon oxide, silicon nitride, or a composite film of a combination of these.

It is noted that the embedded bodies 110C may have a configuration in which an insulating film is formed on the surface of polycrystalline silicon to cause at least a surface portion to have an insulation property.

The FD conversion gain switching transistor 101 includes a channel-forming region 111, a gate insulating film 112, a gate electrode 113, and a pair of non-illustrated main electrodes (114) used as a source region and a drain region.

The channel-forming region 111 is formed using the main surface section of the first semiconductor layer 11. Although its detailed configuration and description are omitted, the channel-forming region 111 is implanted with an impurity for adjusting a threshold voltage.

The gate insulating film 112 is provided on the channel-forming region 111 along this channel-forming region. Here, the gate insulating film 112 is formed of silicon oxide.

The gate electrode 113 is formed on the gate insulating film 112 along this gate insulating film 112. The gate electrode 113 is formed of polycrystalline silicon doped with an impurity for adjusting the resistance value to be smaller.

FIG. 1A illustrates a cross-sectional configuration of the FD conversion gain switching transistor 101 cut along a channel width direction Wc. Thus, although not illustrated, the pair of main electrodes are formed by n-type semiconductor regions spaced apart along a channel length direction Lc centering around the channel-forming region 111.

Here, the channel width direction Wc is a direction corresponding to the arrow X direction. Furthermore, the channel length direction Lc is a direction corresponding to the arrow Y direction.

The FD conversion gain switching transistor 101 includes an n-channel IGFET.

The reset transistor 102 and the selection transistor 104 include an n-channel IGFET as with the FD conversion gain switching transistor 101. Since they have the same structure, description of structures of the reset transistor 102 and the selection transistor 104 is omitted.

### (5) Configuration of Amplification Transistor 103

As illustrated in FIGS. 1A and 1B, the amplification transistor 103 is provided, within a region surrounded by the element separation region 110, in the main surface section of the first semiconductor layer 11. The amplification transistor 103 includes a fin 115, a channel-forming region 111, a gate insulating film 112, a gate electrode 113, and a pair of main electrodes 114. That is, the amplification transistor 103 is a Fin-FET having a fin structure. The amplification transistor 103 is a transistor having a fin structure according to the present disclosure.

The fin 115 is provided to stand on the main surface section of the first semiconductor layer 11. To give a detailed description, the fin 115 is surrounded by the groove 110A of the element separation region 110 formed in the main surface section of the first semiconductor layer 11. The fin 115 is shaped in the main surface section of the first semiconductor layer 11 by the groove 110A dug down from the main surface MS of the first semiconductor layer 11 along a depth direction. In a side view, the fin 115 is formed into the shape of a rectangle or a trapezoid. A dimension of the fin 115 along the arrow Z direction shall be a height dimension. Meanwhile, as viewed from the arrow Z direction (hereinafter, referred to simply as “in a planar view”), the fin 115 is formed into the shape of a rectangle whose sides in the channel length direction Lc are longer than the sides in the channel width direction Wc.

The channel-forming region 111 is provided mostly in the intermediate part of the fin 115 in the channel length direction Lc. To give a detailed description, the channel-forming region 111 is provided in the upper part of the fin 115, the sides of the fin 115, and the lower part of the fin 115. In the upper part of the fin 115, an impurity for adjusting the threshold voltage is implanted as with the channel-forming region 111 of the FD conversion gain switching transistor 101. The sides of the fin 115 are regions corresponding to the sides of the inside of the groove 110A of the element separation region 110. Here, the sides of the fin 115 are not implanted with an impurity for adjusting the threshold voltage. The lower part of the fin 115 is a region corresponding to the bottom of the inside of the groove 110A.

One of the pair of main electrodes 114 is provided in one end of the fin 115 in the channel length direction Lc. The other one of the pair of main electrodes 114 is provided in another end of the fin 115 in the channel length direction Lc through the intervention of the channel-forming region 111. Conveniently, of the pair of main electrodes 114, one main electrode 114 used as a source region is represented by a code “(S)” added to the reference numeral. Likewise, the other main electrode 114 used as a drain region is represented by a code “(D)” added to the reference numeral. The pair of main electrodes 114 are each formed by an n-type semiconductor region.

The gate insulating film 112 is provided on the channel-forming region 111. That is, the gate insulating film 112 is formed, along the channel width direction Wc, on a lower surface and a side surface of one of the sides of the fin 115, on an upper surface of the fin 115, and on a side surface and a lower surface of the other side of the fin 115. In the first embodiment, the gate insulating film 112 is formed of a silicon oxide film.

The gate electrode 113 is provided on the gate insulating film 112. As with the gate insulating film 112, the gate electrode 113 is provided, along the channel width direction Wc, on the lower surface, the side surface, and the upper surface of the fin 115. The gate electrode 113 is formed of polycrystalline silicon doped with an impurity for adjusting the resistance value to be smaller, as with the FD conversion gain switching transistor 101, etc.

The amplification transistor 103 includes an n-channel IGFET, as with the FD conversion gain switching transistor 101, etc.

### (7) Configuration of Electric Field Relaxation Section 116

The amplification transistor 103 having the above-described fin structure includes an electric field relaxation section 116 that relaxes electric field concentration. To give a detailed description, in the first embodiment, the electric field relaxation section 116 is provided in the lower part of the side surface of the fin 115. In other words, the electric field relaxation section 116 is provided along a bottom surface of the groove 110A of the element separation region 110 that constitutes part of the fin 115. To give a further detailed description, the electric field relaxation section 116 is provided at least in the corner of the bottom surface of the groove 110A and a side surface of the groove 110A on the channel-forming region 111 side (the side surface of the fin 115).

In the first embodiment, using the gate insulating film 112 of the amplification transistor 103, the electric field relaxation section 116 is formed of stacked films of the gate insulating film 112 and an insulator 116A.

The gate insulating film 112 is formed, as described above, of a silicon oxide film. To obtain optimum operating characteristics of the amplification transistor 103, the gate insulating film 112 is formed to have a thickness of, for example, between 4 nm and 8 nm, both inclusive.

The insulator 116A is formed of an insulating film having a higher dielectric constant than silicon oxide (a high-k film). As the insulator 116A, one high-dielectric insulating material selected from silicon nitride, aluminum oxynitride (AlON), hafnium oxide (HfO2), nitrogen-doped hafnium silicate (HfSiON), aluminum oxide (Al2O3), lanthanum oxide (La2O3), and cesium oxide (CeO2) is used. In particular, in a case where silicon nitride or aluminum oxynitride is used, in a process of manufacturing the solid-state imaging device 1, a high-temperature heat treatment at about 950° C. is able to be used. To ensure the sufficient dielectric strength of the gate insulating film 112 with an operating voltage applied to the amplification transistor 103, the insulator 116A is formed to have a thickness of, for example, between 1 nm and 10 nm, both inclusive. In the solid-state imaging device 1 according to the first embodiment, the insulator 116A is formed to have a thickness equal to the thickness of the gate insulating film 112, i.e., a thickness of between 4 nm and 8 nm, both inclusive.

### (8) Configuration of First Wiring Layer 12 of First Substrate 10

As illustrated in FIG. 1A, the first wiring layer 12 includes non-illustrated multiple layers of wiring lines, a plug wiring line 121, and an insulating layer 123.

The multiple layers of wiring lines are used as a signal wiring line and a power supply wiring line. The wiring lines are formed of, for example, an aluminum (Al) alloy. The other end of the above-described through wiring line 222 that goes through the second wiring layer 22 of the second substrate 20 is coupled to, for example, the wiring line of the first wiring layer 12.

The plug wiring line 121 is formed to go through the insulating layer 123 in the thickness direction. The plug wiring line 121 is formed of, for example, tungsten, as with the through wiring line 222.

The insulating layer 123 is formed of multiple layers of insulating films, as with the insulating layer 223 of the second wiring layer 22.

### (9) Schematic Configuration of Third Substrate

Although its detailed structure and description are omitted, the third substrate is stacked on the first substrate 10 on the side opposite to the second substrate 20 side. As with the first substrate 10, the third substrate includes a third semiconductor layer and a third wiring layer. A peripheral circuit is mounted in the third semiconductor layer. The peripheral circuit includes a complementary IGFET.

### [Action and Effects]

As illustrated in FIGS. 1A and 1B, the solid-state imaging device 1 according to the first embodiment includes the first semiconductor layer 11, the amplification transistor 103, and the electric field relaxation section 116. The amplification transistor 103 includes the fin 115 provided to stand on the main surface section of the first semiconductor layer 11, and has the fin structure. The electric field relaxation section 116 is provided at least in the lower part of the side surface of the fin 115.

Here, if the operating voltage is applied to the gate electrode 113 of the amplification transistor 103, a potential difference is generated between the gate electrode 113 and the first semiconductor layer 11. In particular, the lower part of the side surface of the fin 115 is the corner of the inside of the groove 110A of the element separation region 110, and electric field concentration occurs in this site. The electric field relaxation section 116 is able to relax the electric field concentration; therefore, the electric field relaxation section 116 makes it possible to improve the dielectric strength of the gate insulating film 112.

As a result of actually conducting a time-dependent dielectric breakdown (TDDB) test, sufficient dielectric strength was obtained, and it was possible to prevent dielectric breakdown of the gate insulating film 112.

Furthermore, in the solid-state imaging device 1, as illustrated in FIGS. 1A and 2, the amplification transistor 103 is included in the pixel circuit 100 coupled to the pixels 200. The amplification transistor 103 adopts the fin structure, which allows a gate width dimension to be made longer in a gate width direction Wc. Thus, it is possible to improve transconductance (gm) characteristics of the amplification transistor 103 while improving the dielectric strength. In addition, it is possible to improve random telegraph signal (RTS) noise characteristics.

Moreover, in the amplification transistor 103 having the fin structure, an impurity for adjusting the threshold voltage is implanted into the upper part of the fin 115, and no impurity is implanted into the sides of the fin 115. Thus, carriers (here, electrons) moving through the channel-forming region 111 in the sides of the fin 115 are less likely to be affected by the interface state than carriers moving through the channel-forming region 111 in the upper part of the fin 115. Accordingly, it is possible to improve low-frequency noise (1/f noise) of the amplification transistor 103 while improving the dielectric strength.

Furthermore, in the solid-state imaging device 1, as illustrated in FIG. 1A, the electric field relaxation section 116 is provided in the lower part of the sides of the fin 115 and the bottom of the groove 110A of the element separation region 110. Thus, the electric field relaxation section 116 has a relatively simple configuration, and is able to be easily formed in the bottom of the groove 110A in the manufacturing process.

Moreover, in the solid-state imaging device 1, as illustrated in FIG. 1A, the electric field relaxation section 116 includes the insulator 116A having a high dielectric constant. Thus, it is possible to increase the gate capacitance generated between the gate electrode 113 of the amplification transistor 103 and the first semiconductor layer 11, which makes it possible to improve the noise characteristics.

Furthermore, in the solid-state imaging device 1, as illustrated in FIG. 1A, the electric field relaxation section 116 includes the gate insulating film 112 of the amplification transistor 103 and the insulator 116A. That is, using the gate insulating film 112, the electric field relaxation section 116 increases in its effective thickness by adding the insulator 116A to the gate insulating film 112. Thus, the simple configuration enables the dielectric strength to be improved.

Moreover, in the solid-state imaging device 1, as illustrated in FIG. 1A, with a silicon oxide film as the gate insulating film 112, the electric field relaxation section 116 includes the silicon oxide film and the insulator 116A formed on the silicon oxide film. Thus, it is possible to increase the gate capacitance of the amplification transistor 103 while increasing the effective thickness of the electric field relaxation section 116. Accordingly, it is possible to improve the noise characteristics while improving the dielectric strength.

Furthermore, in the solid-state imaging device 1, as illustrated in FIG. 1A, the insulator 116A of the electric field relaxation section 116 is formed of silicon nitride or aluminum oxynitride. These high-dielectric materials have a thermal resistance, and thus are able to be used in a manufacturing process including high-temperature heat treatment. Therefore, it is possible to easily form the electric field relaxation section 116 in the process of manufacturing the amplification transistor 103 which includes the high-temperature heat treatment.

### 2. Second Embodiment

The solid-state imaging device 1 according to the second embodiment of the present disclosure is described. It is noted that in the second and subsequent embodiments, the same component or substantially the same component as that of the solid-state imaging device 1 according to the first embodiment is assigned the same reference numeral, and a repetition of description is omitted.

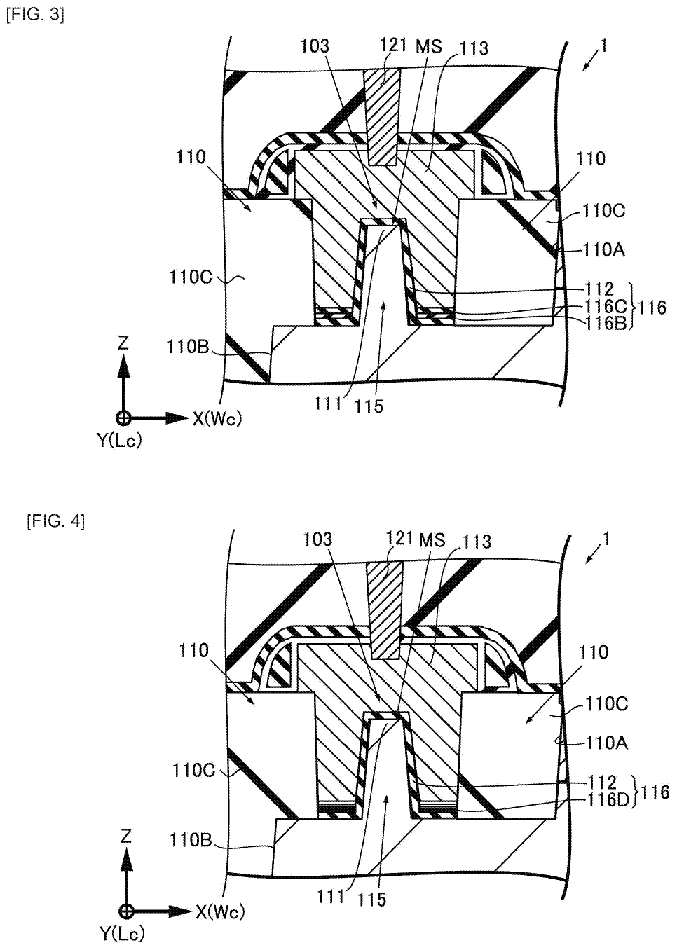

FIG. 3 illustrates a cross-sectional configuration of the amplification transistor 103 having the fin structure. In the solid-state imaging device 1 according to the second embodiment, the electric field relaxation section 116 includes a first insulator 16B and a second insulator 16C provided in the lower part of the sides of the fin 115. The electric field relaxation section 116 includes the gate insulating film 112 as well.

The first insulator 116B of the electric field relaxation section 116 is provided on the gate insulating film 112. The first insulator 116B is formed of an insulating film having a higher dielectric constant than silicon oxide. For example, the first insulator 116B is formed of aluminum oxynitride that is a high-dielectric insulating material described above as an example. The first insulator 116B is formed to have a thickness of, for example, between 2 nm and 4 nm, both inclusive.

The second insulator 116C is provided on the first insulator 116B. The second insulator 116C is formed of an insulating film having a higher dielectric constant than silicon oxide and having a lower dielectric constant than the first insulator 116B. For example, the second insulator 116C is formed of silicon nitride that is a high-dielectric insulating material described above as an example. The second insulator 116C is formed to have a thickness of, for example, between 2 nm and 4 nm, both inclusive.

That is, the electric field relaxation section 116 includes two types of insulators having different dielectric constants: the first insulator 16B and the second insulator 16C. Additionally, the first insulator 116B having a high dielectric constant is provided on the further first semiconductor layer 11 side than the second insulator 116C is. It is noted that the electric field relaxation section 116 may include three or more types of insulators having different dielectric constants.

It is noted that components other than the above are the same as those of the solid-state imaging device 1 according to the first embodiment.

### [Action and Effects]

The solid-state imaging device 1 according to the second embodiment is able to obtain the action and effects similar to those obtained by the solid-state imaging device 1 according to the first embodiment.

Furthermore, in the solid-state imaging device 1 according to the second embodiment, as illustrated in FIG. 3, the electric field relaxation section 116 includes the first insulator 116B and the second insulator 116C. The first insulator 116B has a higher dielectric constant than the second insulator 116C, and is provided on the further first semiconductor layer 11 side than the second insulator 116C is.

Thus, it is possible to increase the gate capacitance of the amplification transistor 103 while increasing the effective thickness of the electric field relaxation section 116 by means of the first insulator 116B and the second insulator 116C. Accordingly, it is possible to improve the noise characteristics while improving the dielectric strength.

### 3. Third Embodiment

The solid-state imaging device 1 according to the third embodiment of the present disclosure is described. FIG. 4 illustrates a cross-sectional configuration of the amplification transistor 103 having the fin structure.

In the solid-state imaging device 1 according to the third embodiment, the electric field relaxation section 116 includes the gate insulating film 112 and a third insulator 116D provided on the gate insulating film 112. The third insulator 116D has a dielectric constant that gradually becomes lower from the lower part toward the upper part of the sides of the fin 115. In other words, the dielectric constant of the third insulator 116D gradually becomes lower from the bottom of the groove 110A of the element separation region 110 towards the opening side of the groove 110A. The phrase “the dielectric constant gradually becomes lower” here means a state where the dielectric constant decreases in stages as well as a state where the dielectric constant continuously decreases.

The third insulator 116D is formed of a high-dielectric insulating material described above as an example. The third insulator 116D is formed to have the same thickness as the insulator 116A of the solid-state imaging device 1 according to the first embodiment. In the formation of the third insulator 116D, for example, a combinatorial method is used.

### [Action and Effects]

The solid-state imaging device 1 according to the third embodiment is able to obtain the action and effects similar to those obtained by the solid-state imaging device 1 according to the second embodiment.

### 4. Fourth Embodiment

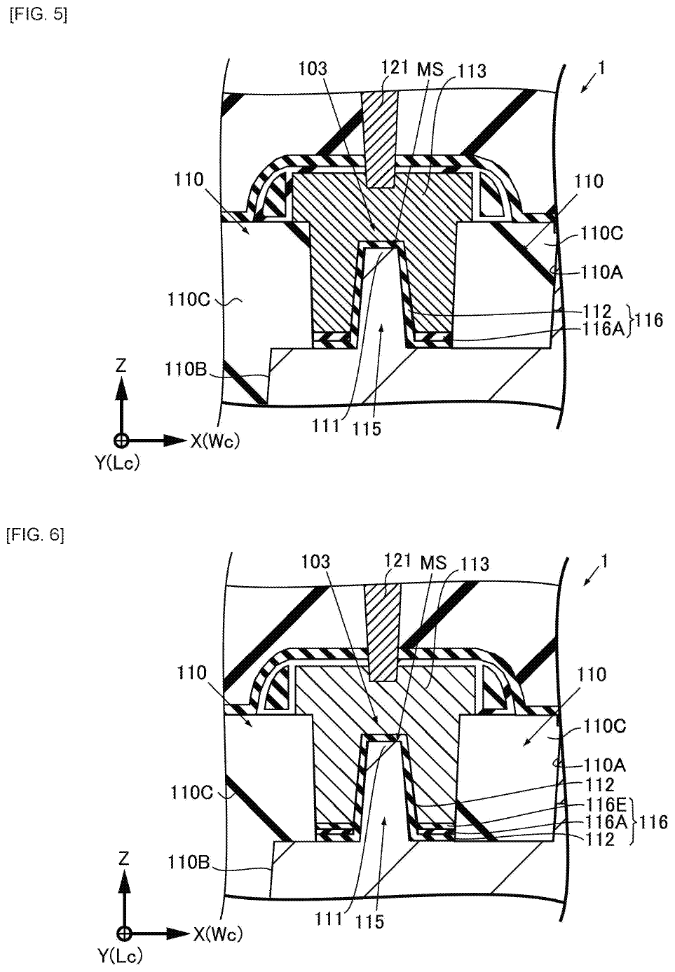

The solid-state imaging device 1 according to the fourth embodiment of the present disclosure is described. FIG. 5 illustrates a cross-sectional configuration of the amplification transistor 103 having the fin structure.

The solid-state imaging device 1 according to the fourth embodiment is a modification example of the solid-state imaging device 1 according to the first embodiment, and the gate electrode 113 of the amplification transistor 103 having the fin structure is formed of metal. As metal materials, titanium (Ti), titanium nitride (TiN), and aluminum are able to be used.

### [Action and Effects]

The solid-state imaging device 1 according to the fourth embodiment is able to obtain the action and effects similar to those obtained by the solid-state imaging device 1 according to the first embodiment.

Furthermore, in the solid-state imaging device 1 according to the fourth embodiment, as illustrated in FIG. 5, the gate electrode 113 of the amplification transistor 103 having the fin structure is formed of metal. If a time-dependent dielectric breakdown test is conducted on the amplification transistor 103, the dielectric strength of the gate insulating film 112 is sufficiently obtained, and it is possible to prevent dielectric breakdown of the gate insulating film 112. Thus, it is possible to further improve the dielectric strength of the amplification transistor 103.

### 5. Fifth Embodiment

The solid-state imaging device 1 according to the fifth embodiment of the present disclosure is described. FIG. 6 illustrates a cross-sectional configuration of the amplification transistor 103 having the fin structure. The solid-state imaging device 1 according to the fifth embodiment is a modification example of the solid-state imaging device 1 according to the first embodiment.

In the solid-state imaging device 1 according to the fifth embodiment, the electric field relaxation section 116 includes the gate insulating film 112, the insulator 116A, and a fourth insulator 116E. As with the gate insulating film 112 of the solid-state imaging device 1 according to the first embodiment, the gate insulating film 112 is formed of a silicon oxide film. The gate insulating film 112 is formed to be, for example, 5 nm in thickness. The insulator 116A is formed of a high-dielectric insulating material having a high dielectric constant. The insulator 116A is formed to be, for example, 6 nm in thickness.

Additionally, the fourth insulator 116E is formed of, for example, a silicon oxide film. The fourth insulator 116E is formed to have a thickness smaller than the respective thicknesses of the gate insulating film 112 and the insulator 116A, for example, to be 1 nm in thickness.

### [Action and Effects]

The solid-state imaging device 1 according to the fifth embodiment is able to obtain the action and effects similar to those obtained by the solid-state imaging device 1 according to the first embodiment.

Furthermore, in the solid-state imaging device 1 according to the fifth embodiment, as illustrated in FIG. 6, the electric field relaxation section 116 includes the gate insulating film 112, the insulator 116A, and the fourth insulator 116E. That is, the electric field relaxation section 116 has a layered structure of silicon oxide, the high-dielectric insulating material, and silicon oxide. By this layered structure, a band offset is formed on the gate electrode 113 side of the amplification transistor 103. Thus, it is possible to block the Fowler-Nordheim (FN) tunneling current between the gate electrode 113 and the first semiconductor layer 11, and is possible to further improve the dielectric strength.

### 6. Sixth Embodiment

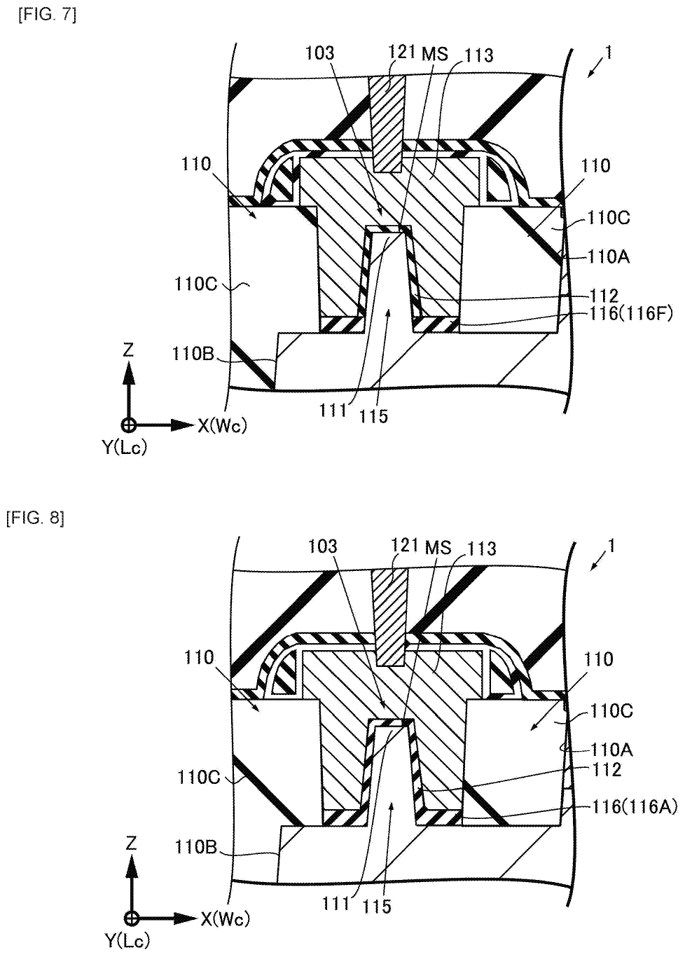

The solid-state imaging device 1 according to the sixth embodiment of the present disclosure is described. FIG. 7 illustrates a cross-sectional configuration of the amplification transistor 103 having the fin structure. The solid-state imaging device 1 according to the sixth embodiment is a modification example of the solid-state imaging device 1 according to the first embodiment.

In the solid-state imaging device 1 according to the sixth embodiment, the electric field relaxation section 116 includes a fifth insulator 116F. The fifth insulator 116F is formed of a film of silicon oxynitride (SiON) that is nitride of silicon oxide of the gate insulating film 112.

To give a detailed description, a portion of the fifth insulator 116F on the first semiconductor layer 11 side is formed as silicon oxide by setting the nitrogen concentration lower, and another portion on the gate electrode 113 side is formed as silicon oxynitride by setting the nitrogen concentration higher. The dielectric constant of silicon oxynitride is higher than the dielectric constant of silicon oxide. The fifth insulator 116F is formed to have a thickness of, for example, between 10 nm and 14 nm, both inclusive.

### [Action and Effects]

The solid-state imaging device 1 according to the sixth embodiment is able to obtain the action and effects similar to those obtained by the solid-state imaging device 1 according to the first embodiment.

### 7. Seventh Embodiment

The solid-state imaging device 1 according to the seventh embodiment of the present disclosure is described. FIG. 8 illustrates a cross-sectional configuration of the amplification transistor 103 having the fin structure. The solid-state imaging device 1 according to the seventh embodiment is a modification example of the solid-state imaging device 1 according to the first embodiment.

In the solid-state imaging device 1 according to the seventh embodiment, the gate insulating film 112 of the amplification transistor 103 having the fin structure is formed of the insulator 116A that is a high-dielectric insulating material described above.

Additionally, the electric field relaxation section 116 is provided at least in the lower part of the side surface of the fin 115, and the gate insulating film 112 is formed to be thicker than the other regions except the upper surface and the lower surface of the fin 115. Here, the electric field relaxation section 116 is provided on the entire area in the bottom of the groove 110A of the element separation region 110.

### [Action and Effects]

The solid-state imaging device 1 according to the seventh embodiment is able to obtain the action and effects similar to those obtained by the solid-state imaging device 1 according to the first embodiment.

### 8. Eighth Embodiment

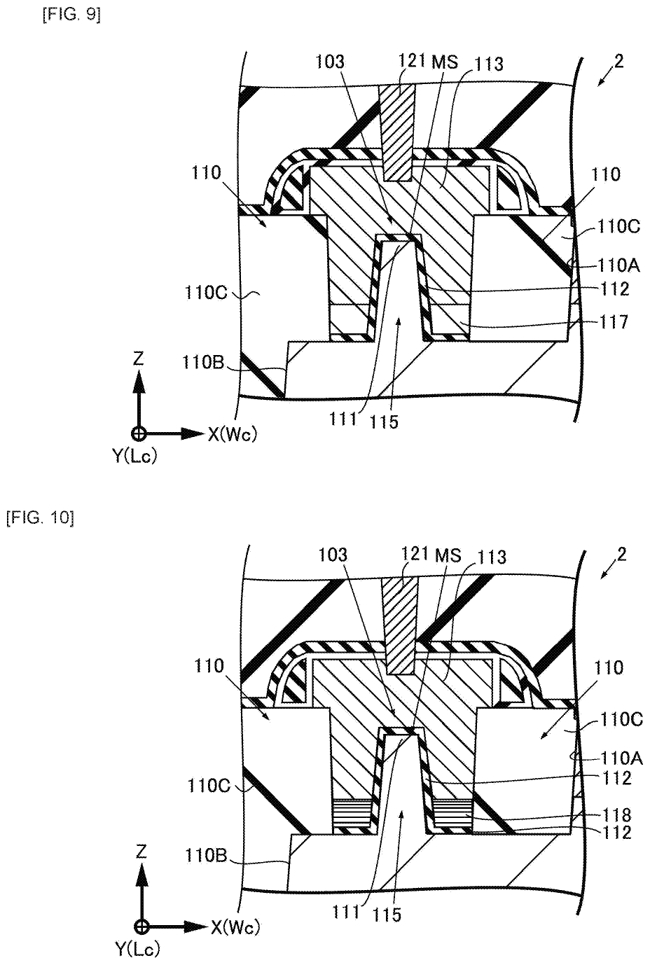

A solid-state imaging device 2 according to the eighth embodiment of the present disclosure is described. FIG. 9 illustrates a cross-sectional configuration of the amplification transistor 103 having the fin structure. There is described an example where in the solid-state imaging device 2 according to the eighth embodiment, the configuration of the electric field relaxation section 116 of the solid-state imaging device 1 according to the first embodiment is modified.

In the solid-state imaging device 2 according to the eighth embodiment, the gate electrode 113 of the amplification transistor 103 having the fin structure is formed of polycrystalline silicon. The polycrystalline silicon is doped with an impurity for adjusting the resistance value to be smaller. For example, phosphorus is used as the impurity, and the gate electrode 113 is formed to have an impurity density of 1×10²⁰ atoms/cm³.

Additionally, as with the electric field relaxation section 116 of the solid-state imaging device 1 according to the first embodiment, the solid-state imaging device 2 according to the eighth embodiment includes an electric field relaxation section 117. The electric field relaxation section 117 is provided in the lower part of the sides of the fin 115 of the amplification transistor 103 having the fin structure. In other words, the electric field relaxation section 117 is provided in the bottom of the inside of the groove 110A of the element separation region 110.

The electric field relaxation section 117 is formed by adjusting the density of the impurity doped into a portion of the polycrystalline silicon of the gate electrode 113 lower. For example, the electric field relaxation section 117 is formed to have an impurity density of 1×10¹⁷ atoms/cm³ or less.

Furthermore, the electric field relaxation section 117 is formed in an area up to 20% of the height of the fin 115. To give a detailed description, for example, in a case where the fin 115 is formed to be 250 nm in height, the electric field relaxation section 117 is formed to be equal to or less than 20 nm in height. If a depletion layer is generated in the electric field relaxation section 117, the effective channel width dimension of the amplification transistor 103 is reduced. Thus, the height of the electric field relaxation section 117 is set to be a dimension equal to the extension of the depletion layer.

In a process of manufacturing the solid-state imaging device 2, the electric field relaxation section 117 is formed, after the gate electrode 113 is doped with the impurity, for example, by setting the anneal temperature lower and activating the impurity. By adopting such a manufacturing process, it becomes possible to form a portion of the gate electrode 113 to be low in density of the impurity.

It is noted that components other than the above are the same as those of the solid-state imaging device 1 according to the first embodiment.

### [Action and Effects]

As illustrated in FIG. 9, the solid-state imaging device 2 according to the eighth embodiment includes the first semiconductor layer 11, the amplification transistor 103, and the electric field relaxation section 117. The amplification transistor 103 includes the fin 115 provided to stand on the main surface section of the first semiconductor layer 11, and has the fin structure. The electric field relaxation section 117 is provided at least in the lower part of the side surface of the fin 115.

Here, if the operating voltage is applied to the gate electrode 113 of the amplification transistor 103, a potential difference is generated between the gate electrode 113 and the first semiconductor layer 11. In particular, the lower part of the side surface of the fin 115 is the corner of the inside of the groove 110A of the element separation region 110, and electric field concentration occurs in this site. At this time, the electric field relaxation section 117 has been formed to be low in density of the impurity in polycrystalline silicon; therefore, it is possible to expand the depletion layer generated in the electric field relaxation section 117 from the interface between the electric field relaxation section 117 and the gate insulating film 112. Accordingly, it is possible to relax the electric field concentration, and the electric field relaxation section 117 makes it possible to improve the dielectric strength of the gate insulating film 112.

As a result of actually conducting a time-dependent dielectric breakdown test, sufficient dielectric strength was obtained, and it was possible to prevent dielectric breakdown of the gate insulating film 112.

Furthermore, in the solid-state imaging device 2, the amplification transistor 103 has the fin structure; therefore, it is possible to obtain the action and effects similar to those obtained by the amplification transistor 103 of the solid-state imaging device 1 according to the first embodiment.

Moreover, in the solid-state imaging device 2, the gate insulating film 112 of the amplification transistor 103 is able to be formed to make the film thickness thin, which makes it possible to increase the gate capacitance. Thus, it is possible to improve the noise characteristics while improving the dielectric strength.

### 9. Ninth Embodiment

The solid-state imaging device 2 according to the ninth embodiment of the present disclosure is described. FIG. 10 illustrates a cross-sectional configuration of the amplification transistor 103 having the fin structure. The solid-state imaging device 1 according to the ninth embodiment is a modification example of the solid-state imaging device 2 according to the eighth embodiment.

The solid-state imaging device 2 according to the ninth embodiment includes an electric field relaxation section 118. The electric field relaxation section 118 is formed to cause the density of the impurity doped into polycrystalline silicon of the gate electrode 113 to gradually become lower from the upper part toward the lower part of the side surface of the fin 115 of the amplification transistor 103 having the fin structure. In other words, the electric field relaxation section 118 has gradation of the impurity density.

It is noted that components other than the above are the same as those of the solid-state imaging device 2 according to the eighth embodiment.

### [Action and Effects]

The solid-state imaging device 2 according to the ninth embodiment is able to obtain the action and effects similar to those obtained by the solid-state imaging device 2 according to the eighth embodiment.

### 10. Tenth Embodiment

The solid-state imaging device 2 according to the tenth embodiment of the present disclosure is described. FIG. 11 illustrates a cross-sectional configuration of the amplification transistor 103 having the fin structure. The solid-state imaging device 1 according to the tenth embodiment is a modification example of the solid-state imaging device 2 according to the eighth embodiment.

The solid-state imaging device 2 according to the tenth embodiment includes an electric field relaxation section 119. The gate electrode 113 of the amplification transistor 103 having the fin structure is formed of polycrystalline silicon. The polycrystalline silicon is doped with an impurity for adjusting the resistance value to be smaller. The electric field relaxation section 119 is formed using a portion of the polycrystalline silicon of the gate electrode 113, and this portion of polycrystalline silicon is not doped with the impurity. That is, the electric field relaxation section 119 is formed of non-dope polycrystalline silicon.

It is noted that components other than the above are the same as those of the solid-state imaging device 2 according to the eighth embodiment.

### [Action and Effects]

The solid-state imaging device 2 according to the tenth embodiment is able to obtain the action and effects similar to those obtained by the solid-state imaging device 2 according to the eighth embodiment.

### 11. Eleventh Embodiment

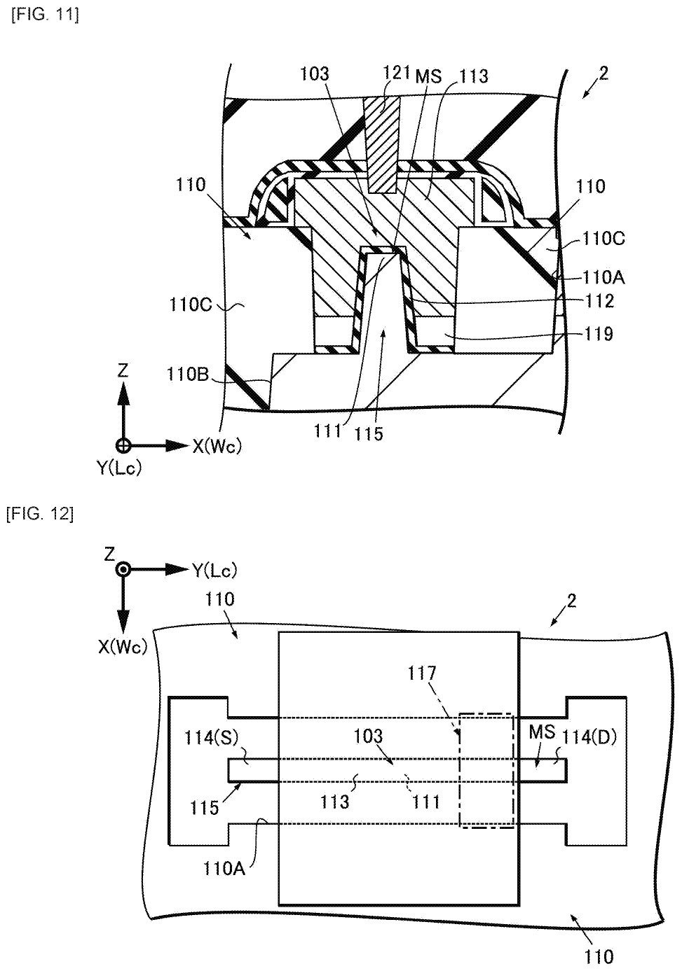

The solid-state imaging device 2 according to the eleventh embodiment of the present disclosure is described. FIG. 12 illustrates a planar configuration of the amplification transistor 103 having the fin structure. The solid-state imaging device 1 according to the eleventh embodiment is a modification example of the solid-state imaging device 2 according to the eighth embodiment.

In the solid-state imaging device 2 according to the eleventh embodiment, the electric field relaxation section 117 of the solid-state imaging device 2 according to the eighth embodiment is provided on the side of the main electrode 114(D) used as a drain region of the amplification transistor 103 having the fin structure. In other words, the electric field relaxation section 117 is provided in a region in which electric field concentration is likely to occur.

It is noted that components other than the above are the same as those of the solid-state imaging device 2 according to the eighth embodiment.

Furthermore, in the solid-state imaging device 2 according to the eleventh embodiment, the electric field relaxation section 118 of the solid-state imaging device 2 according to the ninth embodiment or the electric field relaxation section 119 of the solid-state imaging device 2 according to the tenth embodiment may be provided on the side of the main electrode 114(D) of the amplification transistor 103.

Moreover, the solid-state imaging device 2 according to the eleventh embodiment may be combined with the solid-state imaging device 1 according to any of the first to seventh embodiments.

### [Action and Effects]

The solid-state imaging device 2 according to the eleventh embodiment is able to obtain the action and effects similar to those obtained by the solid-state imaging device 2 according to the eighth embodiment.

### 12. Example of Application to Moving Body

The technique according to the present disclosure (the present technology) is applicable to various products. For example, the technique according to the present disclosure may be realized as a device mounted on any of types of moving bodies such as a motor vehicle, an electric vehicle, a hybrid electric vehicle, a motorcycle, a bicycle, a personal transporter, an airplane, a drone, a vessel, and a robot.

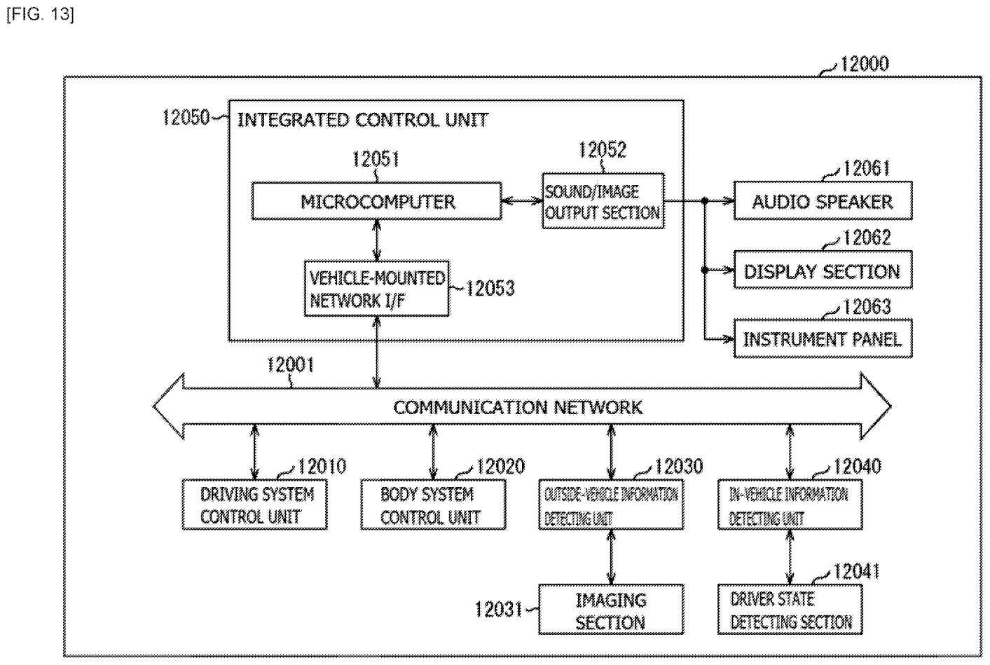

FIG. 13 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 13, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 13, an audio speaker 12061, a display section 12062, and an instrument panel 12063 are illustrated as the output device. The display section 12062 may, for example, include at least one of an on-board display and a head-up display.

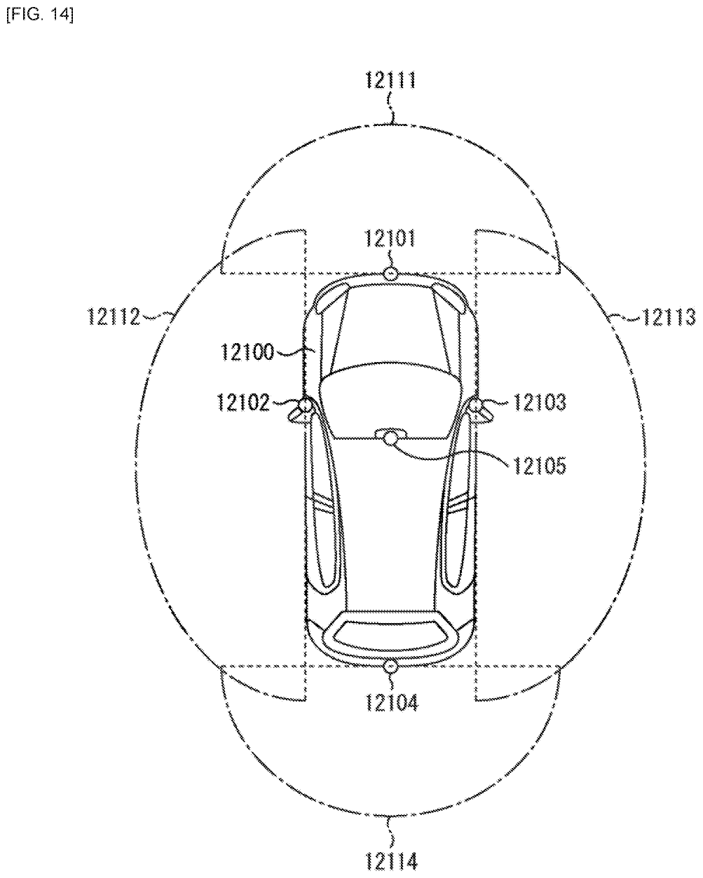

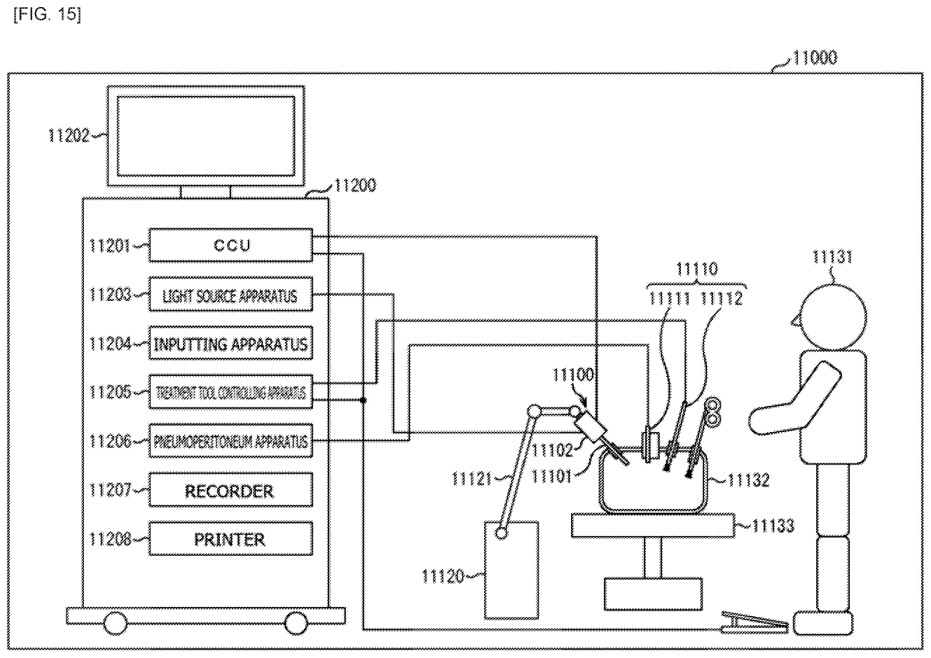

FIG. 14 is a diagram depicting an example of the installation position of the imaging section 12031.

In FIG. 14, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

As above, there is described an example of the vehicle control system to which the technique according to the present disclosure may be applied. The technique according to the present disclosure may be applied to, of the above-described components, the imaging section 12031. By applying the technique according to the present disclosure to the imaging section 12031, it becomes possible to achieve a simpler configuration of the imaging section 12031.

### 13. Example of Application to Endoscopic Surgery System

The technique according to the present disclosure (the present technology) is applicable to various products. For example, the technique according to the present disclosure may be applied to an endoscopic surgery system.

FIG. 15 is a view depicting an example of a schematic configuration of an endoscopic surgery system to which the technology according to an embodiment of the present disclosure (present technology) can be applied.

In FIG. 15, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

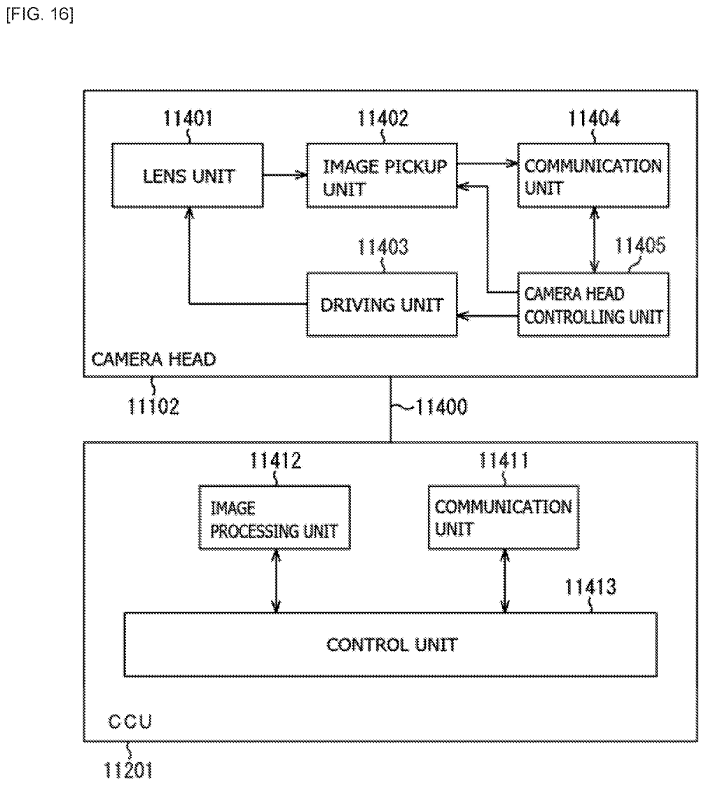

FIG. 16 is a block diagram depicting an example of a functional configuration of the camera head 11102 and the CCU 11201 depicted in FIG. 15.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

As above, there is described an example of the endoscopic surgery system to which the technique according to the present disclosure may be applied. The technique according to the present disclosure may be applied to, of the above-described components, for example, the imaging pickup unit 11402 of the camera head 11102. By applying the technique according to the present disclosure to the imaging pickup unit 11402, it becomes possible to obtain an excellent surgical region image while achieving a simplified structure.

It is noted that here, the endoscopic surgery system is described as an example; however, the technique according to the present disclosure may be applied to other things, for example, a microscopic surgery system or the like.

### 14. Other Embodiments

The present technology is not limited to the above-described embodiments, and it is possible to make various modifications without departing from the scope of the technique.

For example, of the solid-state imaging devices according to the first to eleventh embodiments described above, solid-state imaging devices according to two or more embodiments may be combined.

Furthermore, the present technology is applied to the solid-state imaging device with three layers of substrates stacked on top of another; however, it is also applicable to a solid-state imaging device with two layers of substrates or four or more layers of substrates stacked on top of another.

In the present disclosure, the solid-state imaging device includes a first semiconductor layer, a transistor, and an electric field relaxation section. The transistor includes a fin provided to stand on a main surface section of the first semiconductor layer, and has a fin structure. The electric field relaxation section is provided at least in the lower part of a side surface of the fin. Thus, the electric field relaxation section makes it possible to relax electric field concentration that occurs in the lower part of the side surface of the fin; therefore, it is possible to improve the dielectric strength of a gate insulating film of the transistor.

### <Configuration of Present Technology>

The present technology has the following configuration. According to the present technology having the following configuration, it is possible to improve the dielectric strength of the solid-state imaging device.

(1)

A solid-state imaging device including:
a first semiconductor layer;
a transistor including a fin provided to stand on a main surface section of the first semiconductor layer, a first main electrode, a channel-forming region, a second main electrode, a gate insulating film, and a gate electrode,
   the first main electrode, the channel-forming region, and the second main electrode being provided in the fin along a channel length direction,
   the gate insulating film and the gate electrode covering an upper surface and a side surface of the fin to extend over the fin along a channel width direction; and
an electric field relaxation section provided in the lower part of the side surface of the fin to relax electric field concentration.
   (2)

The solid-state imaging device according to (1), further including:
a second semiconductor layer stacked on the first semiconductor layer; and
pixels each including a photoelectric conversion element provided on a main surface section of the second semiconductor layer on the side opposite to the side of the first semiconductor layer, the pixels being coupled to the transistor,
in which the transistor is an amplification transistor that constitutes part of a pixel circuit.
   (3)

The solid-state imaging device according to (1) or (2), in which
the fin is formed by a groove dug down from a main surface of the first semiconductor layer along a thickness direction, and
the electric field relaxation section is provided in the bottom of the inside of the groove.
   (4)

The solid-state imaging device according to any one of (1) to (3), in which
the electric field relaxation section includes an insulator having a higher dielectric constant than silicon oxide.
   (5)

The solid-state imaging device according to (4), in which
the electric field relaxation section includes the gate insulating film and the insulator formed on the gate insulating film.
   (6)

The solid-state imaging device according to (4), in which
the insulator includes a first insulator and a second insulator formed on the first insulator, the second insulator having a lower dielectric constant than the first insulator.
   (7)

The solid-state imaging device according to (4), in which
the insulator has a dielectric constant that gradually becomes lower from the bottom of the groove toward an opening of the groove.
   (8)

The solid-state imaging device according to (4), in which
the electric field relaxation section includes a first silicon oxide film and the insulator formed on the first silicon oxide film.
   (9)

The solid-state imaging device according to (8), in which
the electric field relaxation section further includes a second silicon oxide film on the insulator.
   (10)

The solid-state imaging device according to (4), in which
the insulator is silicon oxide or aluminum oxynitride.
   (11)

The solid-state imaging device according to (4), in which
the electric field relaxation section is a silicon oxynitride film that is nitride of the gate insulating film.
   (12)

The solid-state imaging device according to (4), in which
the insulator of the electric field relaxation section is formed to be thicker than the insulator formed in a region other than the electric field relaxation section.
   (13)

The solid-state imaging device according to (4), in which
the gate electrode is formed of metal.
   (14)

The solid-state imaging device according to any one of (1) to (3), in which
the gate electrode is formed of polycrystalline silicon doped with an impurity that decreases a resistance value, and
the electric field relaxation section is formed to cause the density of the impurity doped into the gate electrode to be lower than a region other than the electric field relaxation section.
   (15)

The solid-state imaging device according to (14), in which
the electric field relaxation section is formed to cause the density of the impurity to gradually become lower toward the bottom of inside of the groove.
   (16)

The solid-state imaging device according to (14), in which
the electric field relaxation section is formed by the gate electrode not doped with the impurity.
   (17)

The solid-state imaging device according to (4), in which
the electric field relaxation section is formed in an area up to 20% of the height of the fin.
   (18)

The solid-state imaging device according to any one of (1) to (3), in which
the electric field relaxation section is provided on the side of, of the first main electrode and the second main electrode, one used as a drain region.

The present application claims the benefit of Japanese Priority Patent Application JP2021-78800 filed with the Japan Patent Office on May 6, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A solid-state imaging device comprising:
a first semiconductor layer;
a transistor including a fin provided to stand on a main surface section of the first semiconductor layer, a first main electrode, a channel-forming region, a second main electrode, a gate insulating film, and a gate electrode,
the first main electrode, the channel-forming region, and the second main electrode being provided in the fin along a channel length direction,
the gate insulating film and the gate electrode covering an upper surface and a side surface of the fin to extend over the fin along a channel width direction; and
an electric field relaxation section provided in a lower part of the side surface of the fin to relax electric field concentration.

2. The solid-state imaging device according to claim 1, further comprising:
a second semiconductor layer stacked on the first semiconductor layer; and
pixels each including a photoelectric conversion element provided on a main surface section of the second semiconductor layer on a side opposite to a side of the first semiconductor layer, the pixels being coupled to the transistor,
wherein the transistor is an amplification transistor that constitutes part of a pixel circuit.

3. The solid-state imaging device according to claim 1, wherein
the fin is formed by a groove dug down from a main surface of the first semiconductor layer along a thickness direction, and
the electric field relaxation section is provided in a bottom of the groove.

4. The solid-state imaging device according to claim 3, wherein
the electric field relaxation section includes an insulator having a higher dielectric constant than silicon oxide.

5. The solid-state imaging device according to claim 4, wherein
the electric field relaxation section includes the gate insulating film and the insulator formed on the gate insulating film.

6. The solid-state imaging device according to claim 4, wherein
the insulator includes a first insulator and a second insulator formed on the first insulator, the second insulator having a lower dielectric constant than the first insulator.

7. The solid-state imaging device according to claim 4, wherein
the insulator has a dielectric constant that gradually becomes lower from the bottom of the groove toward an opening of the groove.

8. The solid-state imaging device according to claim 4, wherein
the electric field relaxation section includes a first silicon oxide film and the insulator formed on the first silicon oxide film.

9. The solid-state imaging device according to claim 8, wherein
the electric field relaxation section further includes a second silicon oxide film on the insulator.

10. The solid-state imaging device according to claim 4, wherein
the insulator is silicon oxide or aluminum oxynitride.

11. The solid-state imaging device according to claim 4, wherein
the electric field relaxation section is a silicon oxynitride film that is nitride of the gate insulating film.

12. The solid-state imaging device according to claim 4, wherein
the insulator of the electric field relaxation section is formed to be thicker than the insulator formed in a region other than the electric field relaxation section.

13. The solid-state imaging device according to claim 4, wherein
the gate electrode is formed of metal.

14. The solid-state imaging device according to claim 1, wherein
the gate electrode is formed of polycrystalline silicon doped with an impurity that decreases a resistance value, and
the electric field relaxation section is formed to cause a density of the impurity doped into the gate electrode to be lower than a region other than the electric field relaxation section.

15. The solid-state imaging device according to claim 14, wherein
the electric field relaxation section is formed to cause the density of the impurity to gradually become lower toward the bottom of inside of the groove.

16. The solid-state imaging device according to claim 14, wherein
the electric field relaxation section is formed by the gate electrode not doped with the impurity.

17. The solid-state imaging device according to claim 14, wherein
the electric field relaxation section is formed in an area up to 20% of a height of the fin.

18. The solid-state imaging device according to claim 1, wherein
the electric field relaxation section is provided on a side of, of the first main electrode and the second main electrode, one used as a drain region.
